(19) United States
(12) Patent Application Publication
(10) Pub. No.: US 2015/0340305 A1
(43) Pub. Date: Nov. 26, 2015

(54) STACKED DIE PACKAGE WITH REDISTRIBUTION LAYER

(71) Applicant: Wai Yew Lo, Petaling Jaya (MY)

(72) Inventor: Wai Yew Lo, Petaling Jaya (MY)

(73) Assignee: Freescale Semiconductor, Inc., Austin, TX (US)

(21) Appl. No.: 14/281,918

(22) Filed: May 20, 2014

(51) Int. Cl. H01L 23/495; H01L 23/00

(52) U.S. Cl. CPC H01L 23/49517; H01L 24/02; H01L 24/49; H01L 24/85; H01L 2224/0231; H01L 2224/0233

(57) ABSTRACT

A packaged semiconductor device has lead fingers that define a cavity, and a first die located within the cavity. A second die abuts an inactive side of the first die. The second die is electrically connected to one or more of the lead fingers. A redistribution layer abuts an active side of the first die. Metal structures are situated on an outer surface of the redistribution layer. The redistribution layer electrically connects (i) one or more of the metal structures to one or more of the lead fingers and (ii) one or more of the metal structures to one or more bond pads on the active side of the first die.

### BACKGROUND

The present invention relates generally to semiconductor packaging, and, more particularly, to stacked die packages.

In order to assemble a typical chip-on-lead (COL) packaged integrated circuit (IC) device, an IC die is adhesively mounted on and electrically connected to a lead frame. The lead frame is a patterned sheet metal cut-out that includes lead fingers. The IC die is adhesively mounted directly on the lead fingers, rather than onto a separate die flag as is performed in some other types of IC packages.

The lead fingers provide electrical connections between device-internal components on the die and device-external components. Device-external components might include power sources and input/output connections on a printed circuit board (PCB) on which the IC device is mounted. Wire bonding is performed after the die is mounted on the lead fingers of the lead frame. In wire bonding, metal wires are strung between and bonded to bond pads on the die and corresponding lead fingers of the lead frame.

Following wire bonding, the sub-assembly, is mostly encapsulated in molding compound, leaving the distal ends of the leads exposed. The molding compound is subsequently cured. After encapsulation, singulation is performed whereby a plurality of IC devices assembled on a one- or two-dimensional lead frame array are separated into individual IC devices.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows a cross-sectional side view of a packaged semiconductor device according to one embodiment of the present invention;

FIG. 2 shows a top view of the lead frame in FIG. 1 according to one embodiment of the present invention;

FIG. 3 shows a bottom view of the device in FIG. 1 with molding compound removed according to one embodiment of the present invention;

FIG. 4 shows a partial x-ray bottom view of the device in FIG. 1 according to one embodiment of the present invention;

FIGS. 5A-5I show cross-sectional side views that illustrate the steps of an exemplary method of assembling multiple instances of the sensor device of FIG. 1; and

FIG. 6 shows a cross-sectional side view of a packaged semiconductor device according to an alternative embodiment of the present invention.

### DETAILED DESCRIPTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the present invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In the following description, it will be understood that certain embodiments of the present invention are directed to configurations of integrated circuit (IC) die packages comprising a lead frame, at least two dies in a stacked arrangement, and a redistribution layer. For ease of discussion, one particular embodiment is discussed in detail, and some alternative embodiments are described relative to this particular embodiment.

In one embodiment of the present invention, a packaged semiconductor device comprises a plurality of lead fingers defining a cavity, and a first die located within the cavity. A second die abuts an inactive side of the first die, and the second die is electrically connected to one or more of the lead fingers. A redistribution layer abuts an active side of the first die, and a plurality of metal structures are situated on an outer surface of the redistribution layer. The redistribution layer is configured to electrically connect (i) one or more of the metal structures to one or more of the lead fingers and (ii) one or more of the metal structures to one or more bond pads on the active side of the first die.

In another embodiment, the present invention is a method of assembling the above-mentioned packaged semiconductor device.

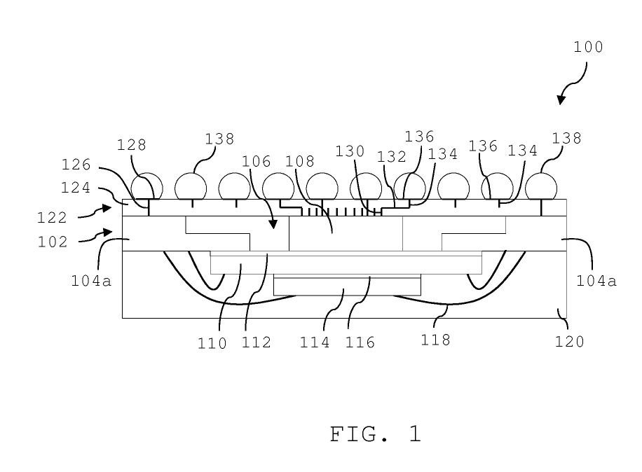

FIG. 1 shows a cross-sectional side view of a packaged semiconductor device 100 according to one embodiment of the present invention. Device 100 comprises a metal lead frame 102 having a cavity 106 formed entirely through the center thereof and a plurality of lead fingers 104a extending from the cavity 106 to a perimeter of the device 100. The lead frame 102 may be fabricated from a single sheet of a suitable conducting metal or alloy such as (without limitation) copper using, for example, etching and/or stamping.

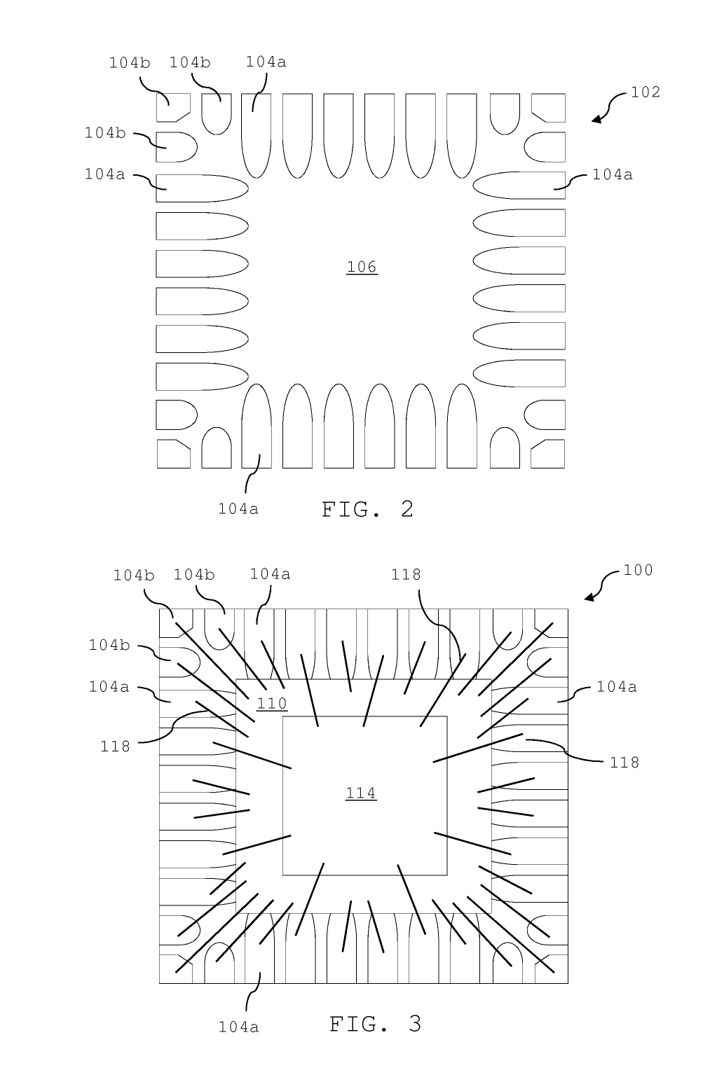

FIG. 2 shows a top view of the lead frame 102 of FIG. 1 according to one embodiment of the present invention. The lead frame 102 has a substantially rectangular (e.g., square) outer shape with a substantially rectangular (e.g., square)-shaped cavity 106 formed in the center thereof. On each side of the lead frame 102, a plurality of similarly-sized and similarly-shaped lead fingers 104a extend from the cavity 106 to the side of the lead frame 102. The lead fingers 104a form a pattern that is substantially similar to that of a conventional quad-flat no-leads (QFN) lead frame. In addition, in each corner of the lead frame 102, a plurality of smaller lead fingers 104b are formed to increase the number of leads on the lead frame 102 over that of an analogous QFN lead frame.

Note that, although FIG. 2 shows one specific pattern of lead fingers, embodiments of the present invention are not so limited. Alternative embodiments of the present invention may be implemented having different patterns and/or numbers of lead fingers, differently-sized and shaped perimeters, and differently-sized and shaped cavities.

Referring back to FIG. 1, the device 100 comprises three dies that are in a stacked arrangement relative to one another: first die 108, second die 110, and third die 114. Each die has (i) an active side having bond pads (not shown) disposed thereon and (ii) an inactive side without bond pads. Each die may be any suitable type of die, and the particular types of dies employed are not essential to the understanding of the present invention.

The first die 108 is situated inside the cavity 106 of the lead frame 102 and between the lead fingers 104a such that the inactive side of the first die 108 abuts a portion of the inactive side of the second die 110. Other portions of the inactive side of the second die 110 abut portions of the lead fingers 104a of the lead frame 102. These elements may be attached to one another using die-attach adhesive 112 such as (without limitation) tape or epoxy. Further, the inactive side of the third die 114 abuts and is attached to a center of the active side of the second die 110 using die-attach adhesive 116 (e.g., tape or epoxy) such that the bond pads (not shown) of the second die 110 are not covered by the third die 114.

One or more and possibly all of the bond pads (not shown) of the second and third dies 110 and 114 are each wire-bonded to a different lead finger 104a or 104b via a bond wire 118 using a suitable wire-bonding process and suitable wire-bonding equipment. The lead fingers 104a and 104b, bond wires 118, and dies 108, 110, and 114 are encapsulated in a molding compound 120. Note that the molding compound 120 also fills the cavity 106 surrounding the first die 108.

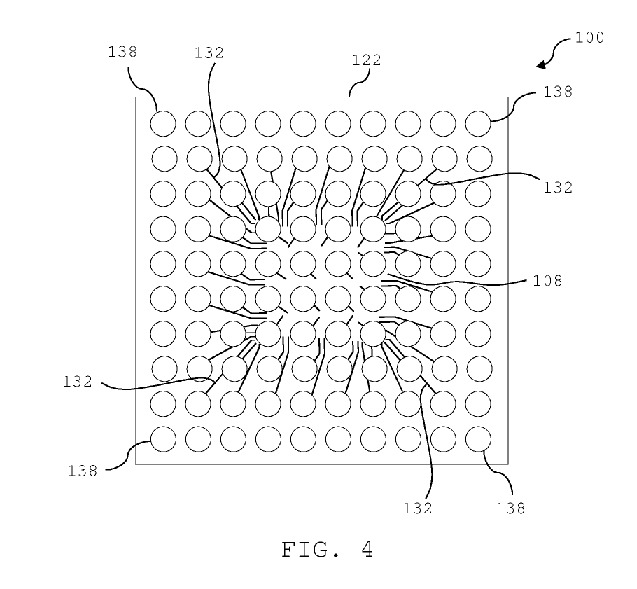

FIG. 3 shows a bottom view of the device 100 with the molding compound removed according to one embodiment of the present invention. As shown, each lead finger 104a and 104b is wire-bonded to a bond pad on one of the second die 110 and the third die 114 via a bond wire 118.

Referring back to FIG. 1, interconnections between the device 100 and the outside world are facilitated by a redistribution layer 122 and solder balls 138. The redistribution layer 122 may be built up in stages using, for example, photolithography and comprises solder resist 124 with a plurality of metal elements formed therein. In particular, the redistribution layer 122 comprises, for each lead finger 104a and 104b, a metal-filled vertical via 126 that extends from the lead finger 104a or 104b to a metal pad 128 of the redistribution layer 122. A solder ball 138 is disposed on each metal pad 128.

Further, the redistribution layer 122 comprises, for the first die 108, a network of metal interconnections, each metal interconnection connecting a bond pad on the active side of the first die 108 to a different metal pad 136 of the redistribution layer 122, upon which a solder ball 138 is disposed. Each metal interconnection comprises a horizontal metal trace 132 having, at one end, a metal-filled vertical via 130 that connects the trace to a bond pad on the active side of the first die 108 and, at the other end of the trace, a metal-filled vertical via 134 that connects the trace to a corresponding metal pad 136.

In some cases, a bond pad on the active side of the first die 108 might be directly connected to a corresponding metal pad 136 using a single vertical via that extends through the entire redistribution layer 122, without using a horizontal trace 132. Note that the metal traces interconnecting some of the metal vias 130 and 134 shown in FIG. 1 extend into or out of the cross-sectional view of FIG. 1 and are therefore not visible in the view of FIG. 1.

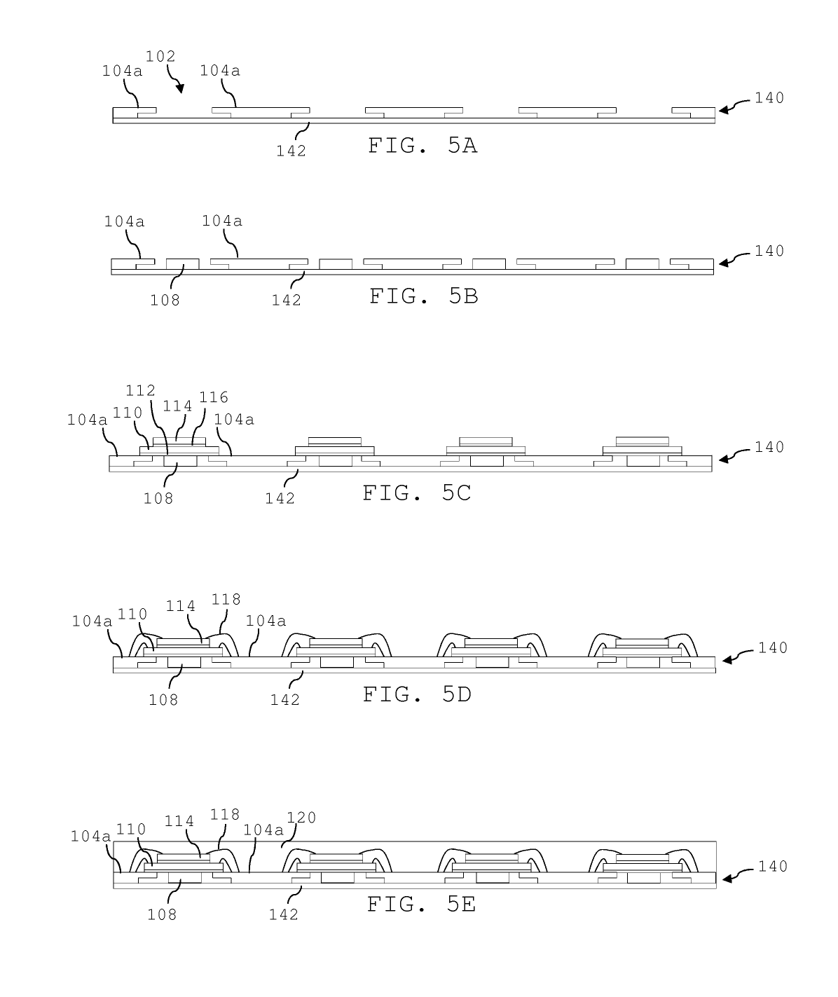

FIG. 4 shows a partial x-ray bottom view of the device in FIG. 1 according to one embodiment of the present invention. This partial view shows the first die 108, the horizontal metal traces 132 of the redistribution layer 122, and the solder balls 138. As shown, each horizontal metal trace 132 begins at a position over a bond pad (not shown) on the first die 108 and extends to a position under a corresponding solder ball 138.

The collection of traces provides fan-out from the relatively closely spaced die bond pads to the more remotely spaced solder balls 138. Note that the specific routing of metal traces 132 may vary from that shown. Further, in this particular implementation, the metal traces 132 do not extend to the perimeter solder balls 138 because these solder balls are interconnected to the lead fingers 104a and 104b using individual metal-filled vertical vias 126 as discussed above.

In at least some embodiments of the present invention, positioning the first die 108 inside the cavity 106 enables the height of the package 100 to be smaller than that of a comparable conventional chip-on-lead (COL) package having three dies stacked on top of lead fingers.

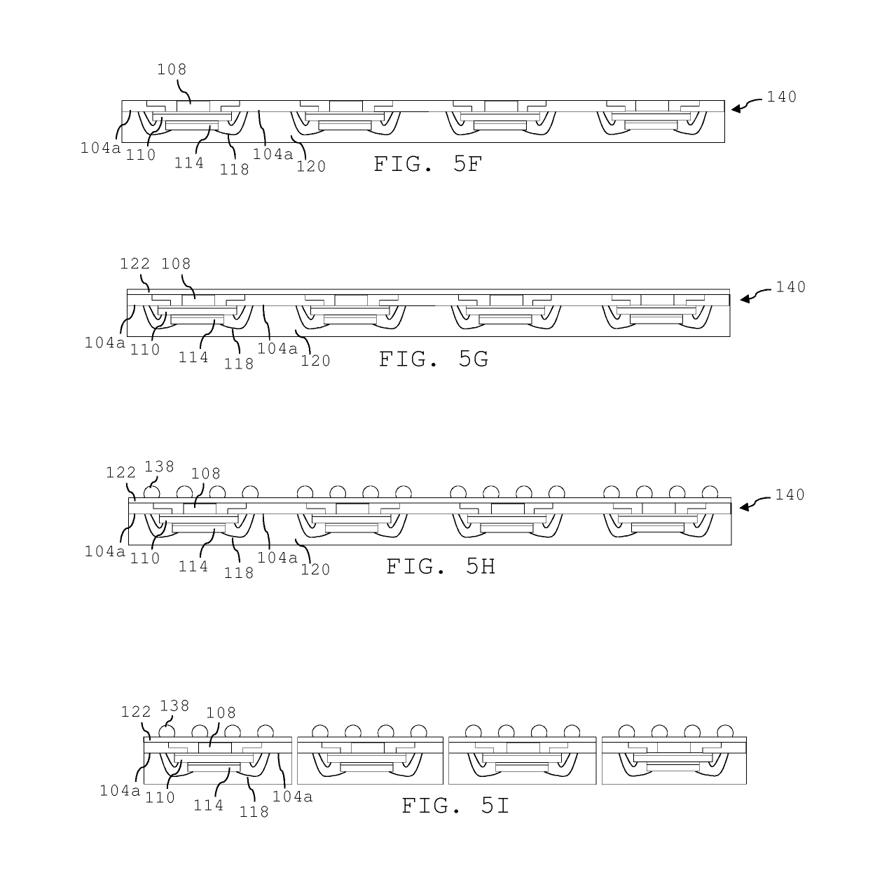

FIGS. 5A-5I show cross-sectional side views that illustrate steps of an exemplary method of assembling multiple instances of the sensor device 100 of FIG. 1.

FIG. 5A illustrates the step of performing lead frame taping, wherein tape 142 is applied to one side of a one- or two-dimensional array 140 of interconnected lead frames. Each lead frame in the array 140 is an instance of the lead frame 102. Further, the array 140 may be formed from a single sheet of metal using, for example, etching and/or stamping.

FIG. 5B illustrates the step of conventional pick-and-place machinery (not shown) mounting multiple instances of the first die 108 onto the tape 142. Each instance of the first die 108 is mounted such that it is positioned inside the cavity 106 of an instance of the lead frame 102 with its active side abutting the tape 142.

FIG. 5C illustrates the step of conventional pick-and-place machinery (not shown) attaching multiple instances of the second die 110 and the third die 114 onto the lead fingers 104a of the lead frames 102. Each second die 110 is attached by adhering its inactive side to the lead fingers 104a of a corresponding lead frame 102 using die-attach adhesive 112. Further, each third die 114 is attached by adhering its inactive side to the active side of a corresponding second die 110 using die-attach adhesive 116. The die-attach adhesives 112 and 116 may subsequently be cured in an oven or via (e.g., UV) light waves to harden the die-attach adhesive.

FIG. 5D illustrates the step of wire-bonding bond wires 118 to electrically connect each second die 110 and each third die 114 to corresponding lead fingers 104a and 104b.

FIG. 5E illustrates the step of applying molding compound 120. The molding compound 120 completely covers the lead fingers 104a and 104b, the second and third dies 110 and 114, and the bond wires 118. Further, the molding compound 120 fills each cavity 106, thereby encasing each first die 108. One way of applying the molding compound 120 is to (i) position a mold (not shown) over the array 140 and (ii) dispense the molding compound 120 into the mold using a nozzle of a conventional dispensing machine. If necessary, the molding compound may be cured, for example, in an oven.

FIG. 5F illustrates the step of removing the tape 142 and flipping over the resulting sub-assembly.

FIG. 5G illustrates the step of forming the redistribution layer 122. As described above, the redistribution layer may be built in steps using, for example, photolithography.

FIG. 5H illustrates the step of applying solder balls 138 to the metal pads of the redistribution layer 122.

FIG. 5I illustrates the step of performing singulation to separate the multiple instances of device 102 into individual devices.

Although FIG. 1 shows one embodiment of the present invention in which solder balls are employed to connect device 100 to the outside world, embodiments of the present invention are not so limited. In alternative embodiments of the present invention, structures other than solder balls may be employed, including (without limitation) metal pads, pins, pillars, and bumps.

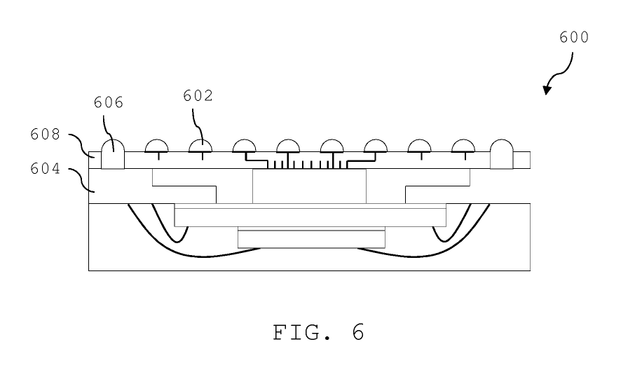

FIG. 6 shows a cross-sectional side view of a packaged semiconductor device 600 according to an alternative embodiment of the present invention. Device 600 is similar to device 100, with at least two differences. First, device 600 employs flip-chip bumps 602, rather than the solder balls 138 of FIG. 1. The bumps 602 may be formed using, for example (without limitation), (i) solder paste printing or similar process and (ii) solder reflow of the printed solder paste to form the bumps.

Second, device 600 employs solder pillars 606 to connect lead fingers 604 to the outside world, rather than employing the metal-filled vias 126, metal pads 128, and solder balls 138 of FIG. 1. The solder pillars 606 may be formed by, for example, (i) forming cavities in the solder resist 608 for the solder pillars, (ii) filling the cavities with solder paste, and (iii) reflowing the solder paste to form the solder pillars 606.

Although FIG. 1 shows three dies stacked onto one another, embodiments of the present invention are not so limited. In alternative embodiments of the present invention, the third die 114 might not be employed, or additional dies might be stacked below the third die 114.

Further, although FIG. 1 shows one embodiment in which the second die 110 is mounted onto the lead fingers 104a, embodiments of the present invention are not so limited. According to alternative embodiments, the second die 110 could be mounted onto the first die 108 using, for example, die-attach adhesive, without being mounted onto the lead fingers 104a. In such embodiments, the footprint of the second die 110 could be the same size or smaller than the footprint of the cavity 106. Alternatively, the footprint of the cavity 106 could be increased, by (i) decreasing the length of the lead fingers 104a or (ii) positioning the lead fingers 104a further away from the center of the cavity 106.

Yet further, although FIG. 1 shows one embodiment in which the inactive side of the second die 110 is adhesively mounted to the lead fingers 104a and the active side of the second die 110 is wire-bonded to the lead fingers 104a, embodiments of the present invention are not so limited. According to alternative embodiments, the active side of the second die 110 may be connected to the lead fingers 104a without bond wires using suitable electrical interconnection techniques such as flip-chip assembly techniques. For example, the second die 110 may be electrically interconnected to the lead fingers 104a through flip-chip bumps attached to the active side of the second die 110. The bumps of the second die 110 are aligned with corresponding lead fingers 104a of the lead frame 102, and the bumps are reflowed to form an electrical and mechanical connection.

Although FIGS. 5A-5I show one method of assembling a packaged semiconductor device, embodiments of the present invention are not so limited. According to alternative embodiments, the order of the steps may be re-arranged and certain steps may even be omitted. For example, the step in FIG. 5C, where the first die 108 is adhesively attached to the second die 110, could be performed before the step in FIG. 5A, where the first die is mounted inside the lead frame 102.

It will be understood that, as used herein, the term “electrical interconnection” refers to a connection that may be made using one or more of bond wires, flip-chip bumps, traces, and other conductors used to electrically interconnect one die to another die or a substrate.

Further, as used herein, the terms “stacked on” and “stacked onto” refer to the relative position of first and second components, with the first component being positioned above or below the second component. It will be understood that, when one component is “stacked on” or “stacked onto” another, the interposition of one or more additional elements or a space is contemplated, although not required. Conversely, the terms “stacked directly on” and “stacked directly onto” implies the absence of such intervening components.

It will be further understood that various changes in the details, materials, and arrangements of the parts which have been described and illustrated in order to explain the nature of this invention may be made by those skilled in the art without departing from the scope of the invention as expressed in the following claims. For example, according to alternative embodiments of the present invention, the number of leads, the number of bond wires, and the connections of bond wires may vary from those show in FIG. 1.

As another example, the shape of the lead frame, the pattern of the lead frame, and the shape of the device 100 may vary.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Terms of orientation such as “lower,” “upper,” “horizontal,” “vertical,” “above,” “below,” “up,” “down,” “top,” “bottom,” “right,” and “left” well as derivatives thereof (e.g., “horizontally,” “vertically,” etc.) should be construed to refer to the orientation as shown in the drawing under discussion. These terms of orientation are for convenience of description and do not require that the apparatus be constructed or operated in a particular orientation.

Unless explicitly stated otherwise, each numerical value and range should be interpreted as being approximate as if the word “about” or “approximately” preceded the value of the value or range.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A packaged semiconductor device, comprising:
a plurality of lead fingers defining a central cavity;
a first die located within the cavity;
a second die abutting an inactive side of the first die, wherein the second die is electrically connected to one or more of the lead fingers;
a redistribution layer abutting an active side of the first die; and
a plurality of metal structures situated on an outer surface of the redistribution layer, wherein the redistribution layer electrically connects (i) one or more of the metal structures to one or more of the lead fingers and (ii) one or more of the metal structures to one or more bond pads on the active side of the first die.

2. The packaged semiconductor device of claim 1, further comprising a third die stacked on the second die, wherein the third die is electrically connected to one or more of the lead fingers.

3. The packaged semiconductor device of claim 1, wherein an inactive side of the second die abuts the inactive side of the first die.

4. The packaged semiconductor device of claim 1, wherein the second die is mounted on one or more of the lead fingers.

5. The packaged semiconductor device of claim 4, wherein an inactive side of the second die is mounted on one or more of the lead fingers.

6. The packaged semiconductor device of claim 5, further comprising a first set of bond wires that electrically connect bond pads on the second die to corresponding ones of the lead fingers.

7. The packaged semiconductor device of claim 6, further comprising:
a third die stacked on the second die; and
a second set of bond wires that electrically connect bond pads on the third die to corresponding other ones of the lead fingers.

8. The packaged semiconductor device of claim 1, wherein the redistribution layer provides fan-out from the first die to the metal structures.

9. A method of assembling a packaged semiconductor device, comprising:
(a) mounting a first die within a cavity defined by a plurality of lead fingers;
(b) attaching a second die to an inactive side of the first die;
(c) electrically connecting the second die to one or more of the lead fingers; and
(d) forming a redistribution layer that abuts an active side of the first die, wherein:
a plurality of metal structures are situated on an outer surface of the redistribution layer; and
the redistribution layer electrically connects (i) one or more of the metal structures to one or more of the lead fingers and (ii) one or more of the metal structures to one or more bond pads on the active side of the first die.

10. The method of claim 9, wherein:
step (b) further comprises attaching a third die on an active side of the second die; and
step (c) further comprises electrically connecting the third die to one or more of the lead fingers.

11. The method of claim 9, wherein step (a) comprises abutting an inactive side of the second die to the inactive side of the first die.

12. The method of claim 9, wherein step (b) comprises mounting the second die on one or more of the lead fingers.

13. The method of claim 12, wherein step (b) further comprises mounting an inactive side of the second die on one or more of the lead fingers.

14. The method of claim 13, wherein step (c) comprises electrically connecting the second die to one or more of the lead fingers with a first set of bond wires.

15. The method of claim 14, wherein:
step (b) further comprises attaching a third die on an active side of the second die; and
step (c) further comprises electrically connecting the third die to one or more of the lead fingers with a second set of bond wires.

16. The method of claim 9, wherein the redistribution layer provides fan-out from the first die to the metal structures.

17. The method of claim 9, wherein:
the method comprises, mounting, before step (a), the plurality of lead fingers onto tape;
step (a) comprises abutting an active side of the first die to the tape;
the method comprises encapsulating, after step (c) but before step (d), at least a portion of the lead fingers, the first die, and the second die in a molding compound; and
step (d) comprises removing the tape before forming the redistribution layer.

18. A packaged semiconductor device assembled in accordance with the method recited in claim 9.
